(19) United States
(12) Patent Application Publication
(10) Pub. No.: US 2005/0216804 A1
(43) Pub. Date: Sep. 29, 2005

(54) Semiconductor device and test method therefor

(75) Inventor: Yoshihisa Sunada, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/088,726

(22) Filed: Mar. 25, 2005

(30) Foreign Application Priority Data
Mar. 29, 2004 (JP) 2004-094477

(51) Int. Cl. G01R 31/28

(52) U.S. Cl. 714/724

(57) ABSTRACT

A multichip package comprises first and second integrated circuits comprising internal cells serving as test objects. The first integrated circuit comprises internal input terminals connected to external terminals for testing, a division multiplexing circuit connected to the internal input terminals, and a first scan control circuit for controlling a scan path test signal of the internal cell. The second integrated circuit comprises internal terminals connected to the division multiplexing circuit via the internal terminals of the first integrated circuit and a second scan control circuit connected to the internal terminals. An external input signal obtained by multiplexing the scan path test signals for the first and second integrated circuits is inputted from the external terminals for testing into the division multiplexing circuit, divided and supplied to the first and second scan control circuits. Scanout signals are received from each scan control circuit, multiplexed, and outputted via the external terminals for testing.

### BACKGROUND OF THE INVENTION

1. Field of the Invention

The present invention relates to a semiconductor device carrying a plurality of integrated circuits, for example, a multichip package, and to a test method therefor.

2. Description of the Related Art

Multichip packages or multichip modules (MCM) carrying in one package a hybrid integrated circuit carrying a plurality of integrated circuits (IC) have been widely used in recent years. Such multichip packages may have a variety of configurations, for example, a stack structure in which a plurality of chips are stacked or a structure in which the chips are arranged in a plane. Therefore, a scan path design method involving a procedure for testing the multichip modules rapidly and at a low cost is required.

A scan path test method is a test facilitation design technology such that sequential circuits such as flip-flops (FF) constituting the functions inherent to the IC are cascade connected to enable a shift register configuration, wherein during the test, a test pattern is serially inputted (scanned in) and taken in (set) into the shift register, test data that were set in the shift register are inputted into the desired combinational logic circuit, and then the output data signals of this logic circuit are taken in the shift register and outputted (scanned out) to the outside. Thus, this is a technology in which in order to improve the control and observation performance of the circuits, the external input terminals are used as control points and the external output terminals are used as the observation points in sequential cells such as flip-flops and latches located inside the circuits. The following scan path test methods are employed: a full scan method in which all the sequential cells are expanded in the combinational circuit in a test mode, and a partial scan method with which conversion is conducted to sequential circuits for which the test pattern is easier to generate. In both cases, the test can be implemented by placing a circuit that is the test object into a special scan cell and additionally using a special scan terminal and a shift register structure (for example, Design Wave Magazine, CQ publication, March 2001, No. 40).

The conventional scan path test method of a multichip package will be explained below. FIG. 9 is a schematic diagram illustrating the conventional multichip package (referred to hereinbelow as Conventional Example 1). As shown in FIG. 9, a multichip package 101 carries a plurality of chips, in this example, an integrated circuit IC11 and an integrated circuit IC12. The integrated circuit IC11 and integrated circuit IC12 are provided with a plurality of respective I/O buffer circuits 102a-102d and 103a-103d, and a plurality of internal terminals 104, 105 respectively connected to the I/O buffer circuits 102a-102d, 103a-103d are connected to the package external terminals 106, 107, respectively.

Further, the integrated circuit IC11 and integrated circuit IC12 have internal cells 108, 109 respectively, and the internal cells 108, 109 have scan control circuits 110, 111 for controlling scan path test signals during respective scan path tests. Flip-flops (FF) in the internal cells 110, 111 can be directly controlled and observed from an external terminal 106A with the scan control circuits 110, 111. Thus, the scan control circuits 110, 111 can set the prescribed states in each FF, and the state of each FF is outputted via the Scanout terminals of the scan control circuits 110, 111. Observing this output makes it possible to test the scan special cells 112, 113 by which the respective sequential cells were replaced in the internal cells 110, 111 in a test mode.

For this purpose, four package external terminals of a plurality of package external terminals 106, 107 serve as test package external terminals 106A, 106B for inputting and outputting the test signals to and from the integrated circuit IC11, IC12 and input a ScanCLK signal, a Scanin signal, and a Scanmode signal, which are the scan path test signals, into the scan control circuits 110, 111 via the internal terminals 107A, 107B connected to the aforementioned package external terminals. The scan control circuits 110, 111 input those scan path test signals into the internal cells 108, 109 serving as the circuits to be tested. For the sake of simplicity, the figure shows only the FF chains 112, 113 that are used when the internal cells 108, 109 are tested. Further, the scan control circuits 110, 111 receive the Scanout signal as a scan path test result from the circuit that is tested, and the test of the internal cells 108, 109 can be conducted by observing this Scanout signal outputted via the external terminals 106A, 106B.

The test package external terminal 106A for the integrated circuit IC11 is composed of a Scanout terminal 106d, a Scanmode terminal 106c, a ScanCLK terminal 106a₁, and a Scanin terminal 106b. The external terminal 106B for inputting the test signal to the integrated circuit IC12 is composed of a Scanout terminal 106g, a Scanmode terminal 106f, a ScanCLK terminal 106a₂, and a Scanin terminal 106e.

Those test external terminals 106A, 106B and internal terminals 107A, 107B of the integrated circuit IC11 and integrated circuit IC12 are respectively connected, and the shift operation of the FF chains 112, 113 can be implemented and the scan path test can be conducted by inputting the scan path test signal to the flip-flop.

FIG. 10 is a timing chart illustrating the scan path test signal for conducting the conventional scan path test of the multichip module shown in FIG. 9. Signals a to g shown in FIG. 10 show the following inputs.
a: input signals of ScanCLK terminals 106a₁, 106b₂ of integrated circuit IC11 and integrated circuit IC12.
b: input signals of Scanin terminal 106b of integrated circuit IC11.
c: input signals of Scanmode terminal 106c of integrated circuit IC11.
d: input signals of Scanout terminal 106d of integrated circuit IC11.
e: input signals of Scanin terminal 106e of integrated circuit IC12.
f: input signals of Scanmode terminal 106f of integrated circuit IC12.
g: input signals of Scanout terminal 106g of integrated circuit IC12.

When the package 101 is tested, test signals are inputted into the integrated circuit IC11 and integrated circuit IC12 from the respective test terminals 106A, 106B via the internal terminals 107A, 107B, and the test of respective internal cells 108, 109 is conducted via the scan control circuits 110, 111 of the integrated circuit IC11 and integrated circuit IC12.

However, when a scan path test of chips is conducted by providing scan special terminals of each chip (integrated circuit IC11 and integrated circuit IC12) as the external terminals 106A, 106B of the package, as in the conventional test method shown in FIG. 9, as a method for conducting a scan path test with a multichip package carrying a plurality of chips or modules, the problem is that a scan special terminal for each chip and a package external terminal for a test connected to each scan special terminal individually are required and the number of package external terminals necessary for the test is increased.

With respect to the multichip module 101 shown in FIG. 9, a multichip module configuration can be employed in which the test external terminal 106A of only one integrated circuit IC11 is used and the other test external terminal 106B is not required. FIG. 11 is a schematic drawing illustrating a multichip module allowing the scan path test to be conducted by using only one test external terminal 106A (referred to hereinbelow as Conventional Example 2). In the multichip module 201 shown in FIG. 11, the constituent elements identical to those of the multichip module 101 shown in FIG. 9 are assigned with the same reference symbols and the detailed explanation thereof is omitted.

In the multichip module 201 shown in FIG. 11, a FF chain 120 capable of shift operation is incorporated between the inner cell 108 and the I/O buffer units 102a to 102d of the integrated circuit IC11. Furthermore, the integrated circuit IC21 and integrated circuit IC22 are connected by the internal terminals 108A and 108B, respectively. The test external terminal 106A is connected only to the internal terminal 107A of the integrated circuit IC21, and the scan special internal terminal 108B of the integrated circuit IC22 is connected to the special internal terminal 108B of the integrated circuit IC21, rather than to the test external terminal. As a result, the state of the internal terminal 107A of the integrated circuit IC21 connected to the external terminal 106A of the integrated circuit IC21 can be transmitted to the scan special terminal 108B on the side of the integrated circuit IC22 via the internal terminal 108A by a shift operation of the FF chain 120 and a scan path test of the integrated circuit IC22 can be conducted from the side of the integrated circuit IC21. Furthers the technology of incorporating the FF capable of switching between the terminal I/O buffer unit and the internal cell and inducing a shifting operation has been disclosed in a Japanese Unexamined Patent Application Publication No. 7-35817.

In the example shown in FIG. 11, the signals inputted from the test external terminal 106A are inputted into the internal terminal 107C of the integrated circuit IC22 from the internal terminal 107B via the internal terminal 107A by inducing a shift operation of the FF chain 120 composed of a 21-stage shift chain.

Thus, if a shift operation described in the Conventional Example 2 is used, when a configuration shown in FIG. 11 is employed, for example, in the Scanin terminal 106b of the integrated circuit IC11, the scan path test signals can be transmitted by conducting 21 shift operation with the 21-stage shift chain in the I/O buffer circuits 102d, 102c, 102b from the FF 120₁ of the FF chain 120 capable of shifting in the I/O buffer connected to the Scanin terminal 106b to the FF 120₂₁ capable of shifting in the I/O buffer of the terminal of the integrated circuit IC11 connected by the chip wiring to the Scanin terminal of the integrated circuit IC12.

FIG. 12 is a timing chart illustrating signals employed during a scan path test in the multichip package 201 shown in FIG. 11. Signal A of FIG. 12 shows a ScanCLK terminal input of IC21, signal B of FIG. 12 shows a Scanin terminal input of IC21, signal C of FIG. 12 shows an output during shift operation of FF 120₁ of the I/O buffer circuit, signal D of FIG. 12 shows an output during shift operation of FF 120₂₁ of the I/O buffer circuit, signal E of FIG. 12 shows a Scanin unit input of Chip2, and signal F of FIG. 12 shows a Scanout terminal output.

When a value of “1100” is inputted into the Scanin terminal on the side of the integrated circuit IC22 to conduct the scan path test of the integrated circuit IC22 in the configuration shown in FIG. 11, first, “1” is inputted to the scanin terminal of the integrated circuit IC21 and then data contained in the FF chain 120 capable of shift operation are shifted by 1 with a clock of ScanCLK contained in the I/O buffer circuit. Then, after “1” has been inputted, data present in the FF chain 120 are similarly shifted by 1. Then, “0” is inputted and data present in the FF chain 120 are shifted by 1. Then, “0” is inputted and the shift operation of the FF chain 120 is then shifted 18 times thereby storing one data initially inputted from the scanin terminal 106b of the integrated circuit IC21 into the next FF120₂₁. Because the FF120₂₁ is connected to the scanin terminal of the integrated circuit IC22 with the chip wiring, the data is transmitted to the scanin terminal of the integrated circuit IC12.

However, in the above-described case shown in FIG. 11, even though the number of package external terminals necessary for the scan path test does not increase despite the increase in the number of integrated circuits as test objects, because the configuration is employed in which the signals inputted from the scan special terminal of the integrated circuit IC21, which is the package external terminal, are transmitted to the scan special terminal of the integrated circuit IC22 by the shift operation of the FF chain 120, the input signals have to be subjected to shift operation from the scan special terminal of the integrated circuit IC21 to the FF 120₂₁ which drives the I/O buffer of the integrated circuit IC21 connected to the scan special terminal of the integrated circuit IC22, the test time increases due to extra shift operations, and the number of shift patterns increases also due to the shift operation.

Thus, comparing the timing chart shown in FIG. 10 and the timing chart shown in FIG. 12, it is clear that in the timing chart shown in FIG. 12, a very long overhead period of t15 to t31 is necessary when the integrated circuit IC22 is tested due to the extra shift operation.

### SUMMARY OF THE INVENTION

According to one aspect of the present invention, there is provided an semiconductor device carrying a plurality of integrated circuits which includes a plurality of external terminals, two or more integrated circuits as test objects and a signal conversion circuit for receiving external input signals from the external terminals, converting the external input signals into test signals for each integrated circuit with respect to the two or more integrated circuits, and outputting the converted test signals to each of the two or more integrated circuits.

According to another aspect of the present invention, there is provided a test method for a semiconductor device carrying a plurality of integrated circuits which includes receiving external input signals via external terminals, converting the external input signals into test signals for each integrated circuit with respect to two or more integrated circuits serving as test objects, outputting the converted test signals to the two or more integrated circuits, and receiving signals indicating the test results from the respective integrated circuits and converting the received signals into one signal and outputting the same.

In accordance with the present invention, when a semiconductor device having two or more integrated circuits is tested, the external input signals inputted via external terminals are converted into test signals for each integrated circuit to test each integrated circuit and outputted to each integrated circuit. As a result, in the integrated circuit for supplying the test signals from the signal conversion circuit, the connection to the external terminal for receiving the test signals becomes unnecessary and the number of external terminals for the test can be minimized.

Therefore, the test time can be shortened without increasing the number of external terminals of the package provided for the test.

### BRIEF DESCRIPTION OF THE DRAWINGS

The above and other objects, advantages and features of the present invention will be more apparent from the following description taken in conjunction with the accompanying drawings, in which:

FIG. 1 illustrates schematically the circuit configuration in the multichip package of an embodiment of the present invention;

FIG. 2 is a circuit diagram illustrating a configuration example of a scan path flip-flop group for conducting a scan path test;

FIG. 3 is a timing chart illustrating an example of a scan path signal;

FIG. 4 illustrates a signal inputted to and outputted from a division multiplexing circuit in a multichip package of an embodiment of the present invention;

FIG. 5 is a circuit diagram illustrating the division multiplexing circuit;

FIG. 6 is the timing chart of the signals inputted into the division multiplexing circuit and the signals converted and outputted from the division multiplexing circuit;

FIG. 7 illustrates a modification example of the embodiment of the present invention and shows a circuit diagram illustrating the division multiplexing circuit in the multichip package;

FIG. 8 is the timing chart of the signals inputted into the division multiplexing circuit in the aforementioned modification example and signals outputted therefrom;

FIG. 9 is a schematic drawing illustrating the multichip package of Conventional Example 1;

FIG. 10 is the timing chart illustrating the scan path test signals for conducting a scan path test of the multichip package of Conventional Example 1 shown in FIG. 9;

FIG. 11 is a schematic drawing illustrating the multichip module of Comparative Example 2; and

FIG. 12 is the timing chart illustrating the scan path test signals for conducting a scan path test of the multichip package of Comparative Example 2 shown in FIG. 11.

### DESCRIPTION OF THE PREFERRED EMBODIMENTS

Specific embodiments employing the present invention will be described below with reference to the appended drawings. In the embodiments, the present invention was employed with respect to a multichip package carrying a plurality of integrated circuits IC and a scan path test control method therefor.

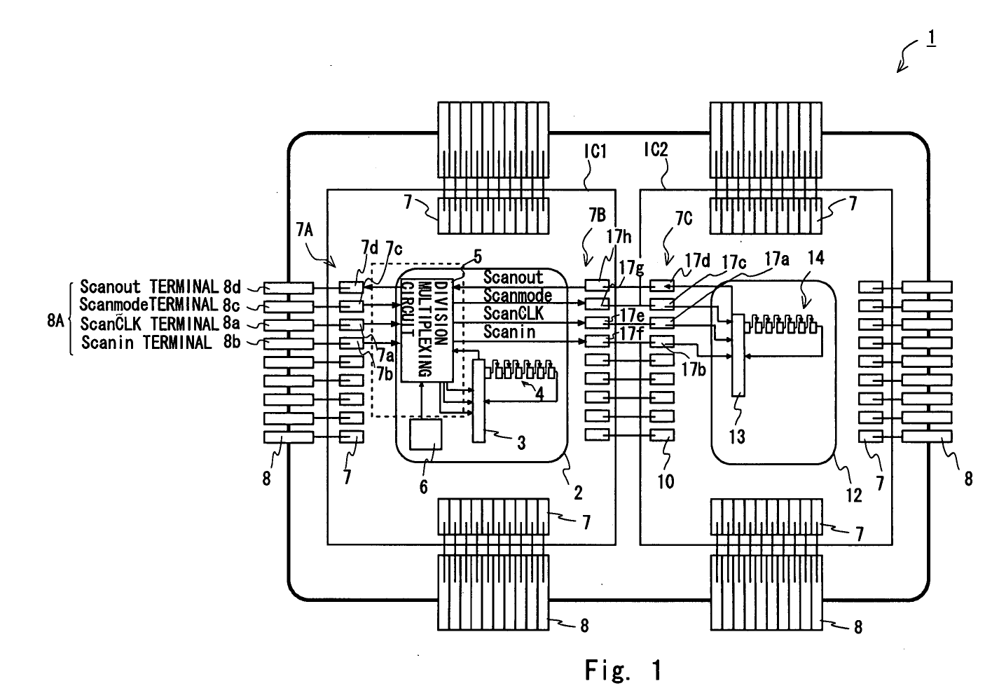

FIG. 1 is a circuit diagram illustrating schematically the circuit configuration in the multichip package of the present embodiment. As shown in FIG. 1, in the multichip package 1, two integrated circuits, namely, the integrated circuit IC1 as the first integrated circuit and the integrated circuit IC2 as the second integrated circuit are carried in a single package. Further, in the present embodiment, the explanation is conducted with respect to two integrated circuits IC carried in a multichip package, but it goes without saying that the number of integrated circuits IC carried in one module is not limited to two and may be three or more. Further, the integrated circuit structure may have a stack structure consisting of a plurality of stacked integrated circuits IC, and not only the planar arrangement.

The integrated circuit IC1 comprises a plurality of internal terminals 7 and an internal cell 2 as a test cell serving as a test object. The internal cell 2 has a scan control circuit 3 for controlling the scan path test signals, a division multiplexing circuit 5 as a signal conversion circuit for inputting the scan path test signals into the scan control circuit 3, and a pulse generation circuit 6 for inputting the standard (reference) pulses into the division multiplexing circuit 5. The division multiplexing circuit 5 is connected to an internal terminal 7A, which is connected to an external 8A to which the scan path test signals are supplied, among the internal terminals 7 of the integrated circuit IC1, and also connected to the internal terminal 7B connected to the internal terminal 7C of the integrated circuit IC2. Further, the internal cell 2 comprises a shift register 4 composed of a FF chain capable of shift operation and uses it during a scan path test of the sequential circuits located inside the internal cell 2.

The internal terminals 7A for testing are a Scanout internal terminal 7d for outputting respective Scanout signals, a Scanmode internal terminal 7c for inputting the Scanmode signals, a ScanCLK internal terminal 7a for inputting the ScanCLK signal, and a Scanin internal terminal 7b for inputting the Scanin signal. Those internal terminals 7A for testing are connected to external terminals 8A for testing that are used for conducting the scan path test, of the external terminals 8 for connecting the package 1 to the external device.

The integrated circuit IC2 comprises an internal cell 12 as a test circuit serving as a test object, and the internal cell 12 has a scan control circuit 13 for controlling the scan path test signals when the scan path test of the internal cell 12 is conducted. Furthermore, the internal cell 12 comprises a shift register 14, and this shift register is used for the scan path test of the sequential circuits located inside the internal cell 12.

External input signals obtained by multiplexing the scan path test signals for conducting a scan path test of the internal cell 2 and internal cell 12 of the integrated circuit IC1 and integrated circuit IC2, respectively, are inputted via the external terminals 8A for testing into the division multiplexing circuit 5. The division multiplexing circuit 5 divides those multiplexed external input signals into the scan path test signals of the internal cell 2 and internal cell 12 and outputs them to the scan control circuit 3 and to the internal terminals 7B (Scanout internal terminal 7h, Scanmode internal terminal 7g, ScanCLK internal terminal 7e, Scanin internal terminal 7f) of the integrated circuit IC1 connected to the internal terminals 7C (Scanout internal terminal 17d, Scanmode internal terminal 17c, ScanCLK internal terminal 17a, Scanin internal terminal 17b) of the integrated circuit IC2, respectively, thereby providing for exchange of scan path test signals between the scan control circuit 3 of the integrated circuit IC1 and scan control circuit 13 of the integrated circuit IC2. The internal terminals 7B, 7C are not connected to the external terminals 8 of the package 1, and those internal terminals 7B, 7C cannot be directly used from the outside.

Furthermore, the Scanout signal as a test result signal, which is the output (scan-out) taken out as a result of inputting (scanning in) the test pattern into the internal cell 2 of the integrated circuit IC1, is inputted into the division multiplexing circuit 5 via the scan control circuit 3. Further, the Scanout signal which is the test result signal obtained by scan path testing the internal cell 12 of the integrated circuit IC2 is inputted into the division multiplexing circuit 5 via the scan control circuit 13 and internal terminal 7C, 7B. The division multiplexing circuit 5 multiplexes those Scanout signals and outputs them from the Scanout external terminal 8d via the Scanout internal terminal 7d.

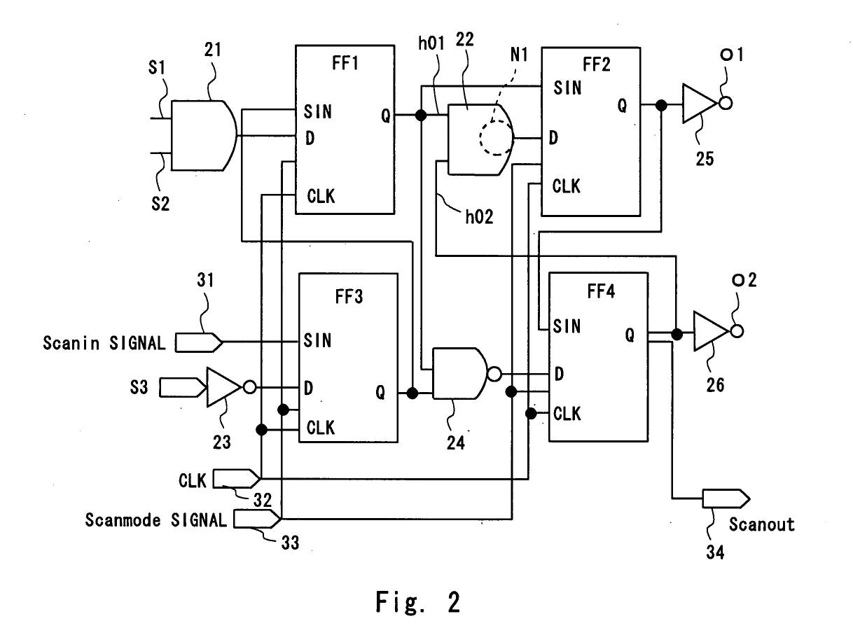

The circuit configuration inside the package of the present embodiment will be described below. FIG. 2 is a circuit diagram illustrating the configuration of the scan path flip-flop group for conducting the scan path test. The scan path test circuit has a general configuration and no limitation is placed thereon. Here, to simplify the explanation, a method for implementing the scan path test by using only four flip-flop circuits FF1 to FF4 will be explained.

In the flip-flop circuits FF1 to FF4, D is a data input terminal, CLK is a clock input terminal, SIN is a scan data input terminal for inputting scan data, and Q is a data output terminal. A selector (not shown in the figures) is provided which can select the data input terminal D and scan data input terminal SIN if a Scanmode signal switching the usual mode and scan mode is inputted. The Scanmode signal and the clock signal CLK are inputted from a Scanmode terminal 33 and a CLK terminal 32 to all of the flip-flop circuits FF1 to FF4, respectively.

The output of an AND gate 21 that inputs two signals S1 and S2, is connected to the data input terminal D of the flip-flop circuit FF1, and the data output terminal Q of the flip-flop circuit FF3 is connected to the scan data input terminal SIN. The data input terminal D of the flip-flop circuit FF2 is connected to the output of an AND gate 22 having as an input thereof a signal (node h01) from the data output terminal Q of the flip-flop FF1 and the signal (node h02) from the data output terminal Q of the flip-flop FF4. Further, the signal (node h01) from the data output terminal Q of the flip-flop circuit FF1 is inputted into the scan data input terminal SIN of the flip-flop circuit FF2.

Scan data are inputted into the scan data input terminal SIN of the flip-flop circuit FF3 via the Scanin terminal 31, and the configuration is such that the signal S3 is inputted into the data input terminal D via an inverter 23. Further, the data output from the data output terminal Q of the flip-flop circuit FF3 is inputted together with the signal (node h01) from the data output terminal Q of the flip-flop circuit FF1 into a NAND gate 24, and the output thereof is inputted into the data input terminal D of the flip-flop circuit FF4. Data from the data output terminal Q of the flip-flop circuit FF2 are inputted into the scan data input terminal SIN of the flip-flop circuit FF4, and the data output terminal Q of the flip-flop circuit FF4 is connected to the Scanout terminal 34 for outputting the scan data output.

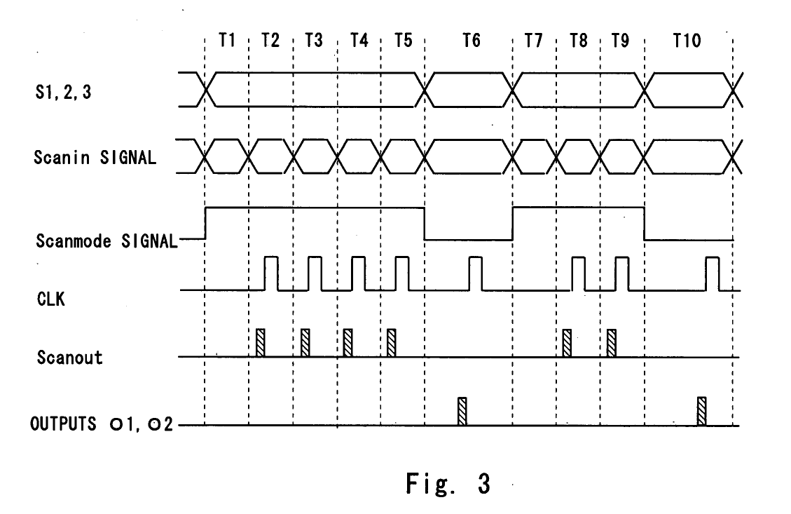

With such a scan path, values may be set in the FF1 and FF3 and the value of an output node N1 may be read from FF2, for example, in order to conduct 0 failure detection of the output node N1 of the AND gate 22. This is done so that all the FF can have a shift register structure and the values can be directly set into each FF and read by shifting. The operation of the scan path test will be explained below. FIG. 3 is a timing chart illustrating the scan path test signals.

First, the input nodes h01, h02 of the NAND gate 22 are set to 1. In this case, in order to set the outputs of FF1 and FF4 to 1, the Scanmode signal inputted from the Scanmode terminal 33 is set to 1 and a scan mode is obtained (T1).

Then, a value of 1xx1 is set with 4 clocks from the Scanin terminal 31 (T2 to T5). At this time, the state of the output node N1 of the NAND gate 22 is observed as the output signals O1, O2 obtained by inverting the output data of FF2 and FF4 with inverters 25, 26, respectively, and the output of the Scanout terminal 34 is observed.

Then, the Scanmode signal is set to 0 and a usual mode is obtained. In the usual mode, the value of the output node N1 of the AND gate 22 is introduced from the data input terminal D of FF2 (T6). In this case, too, the output signals O1, O2 and the output of the Scanout terminal 34 are observed.

Then, the Scanmode signal is again set to 1 to obtain a scan mode, the clock is operated through two turns to shift the data of FF1, FF2 (T7 to T9), and the Scanout signal outputted from the Scanout terminal 34 is observed (T10).

The scan path test is thus usually executed in each integrated circuit, but the scan path test signal (shown in FIG. 3), which is used in this process, has to be supplied to the scan control circuit of the test circuit of each integrated circuit.

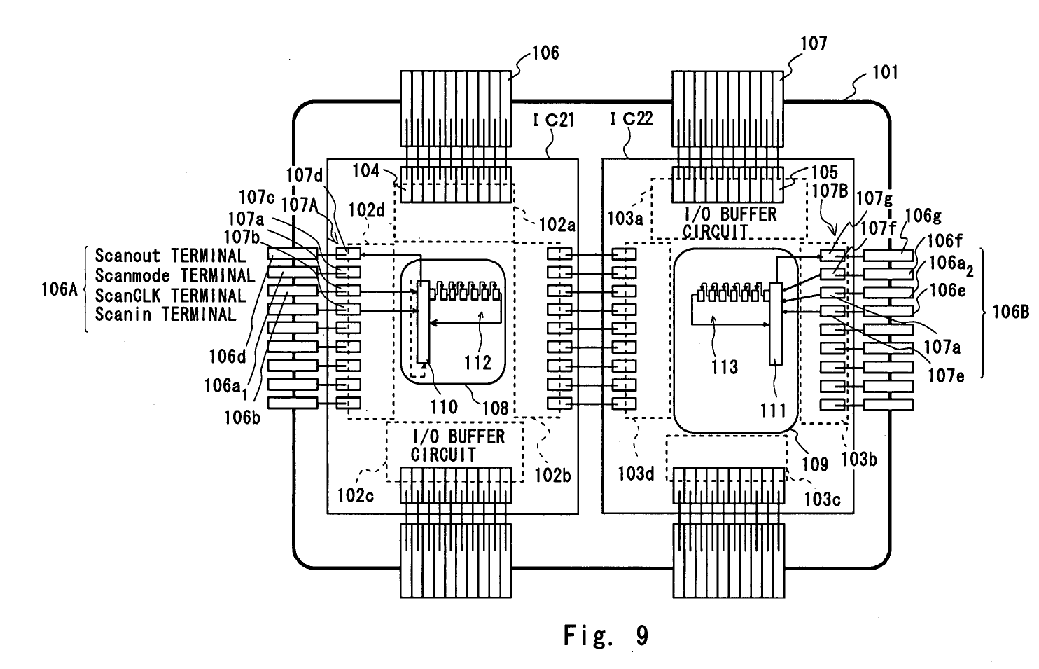

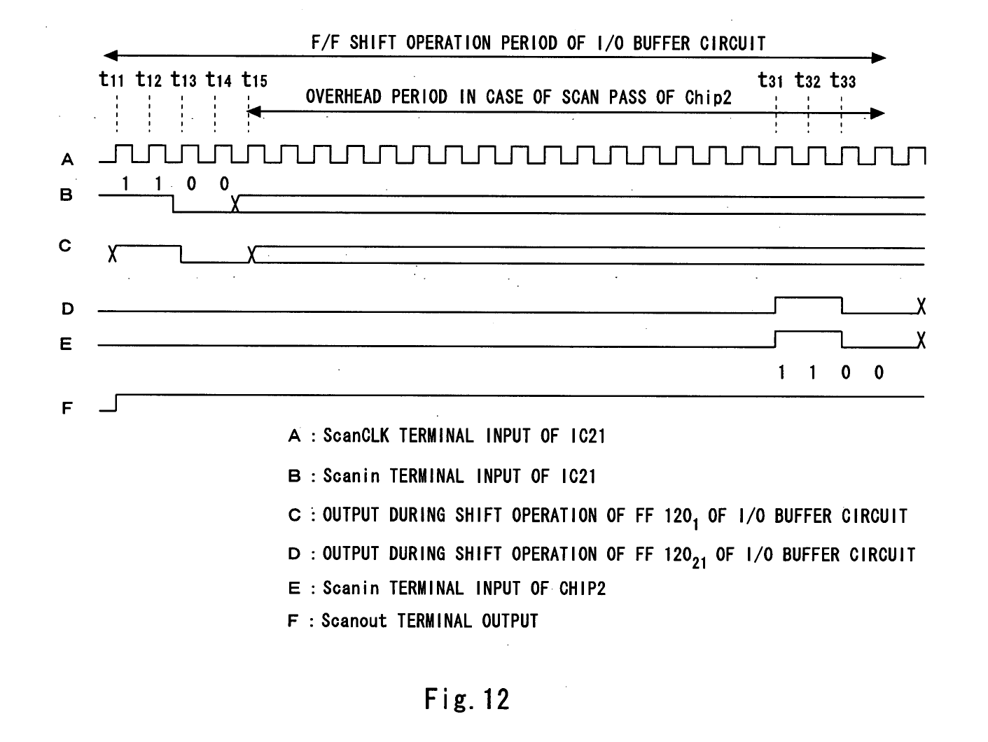

In the present embodiment, scan path test signals for the internal cell of the test object are inputted upon multiplexing, divided in the division multiplexing circuit 5, and outputted in parallel to each test circuit, thereby making it unnecessary to use a large number of external terminals for testing that are shown in FIG. 9, and eliminating the overhead interval such as shown in FIG. 12.

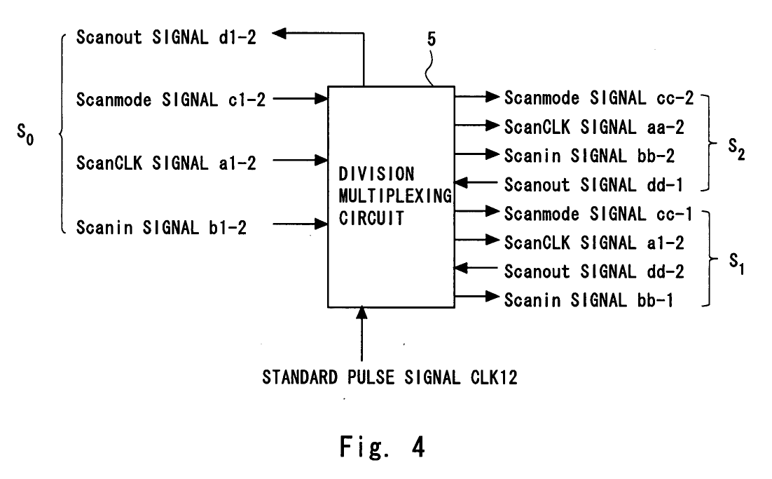

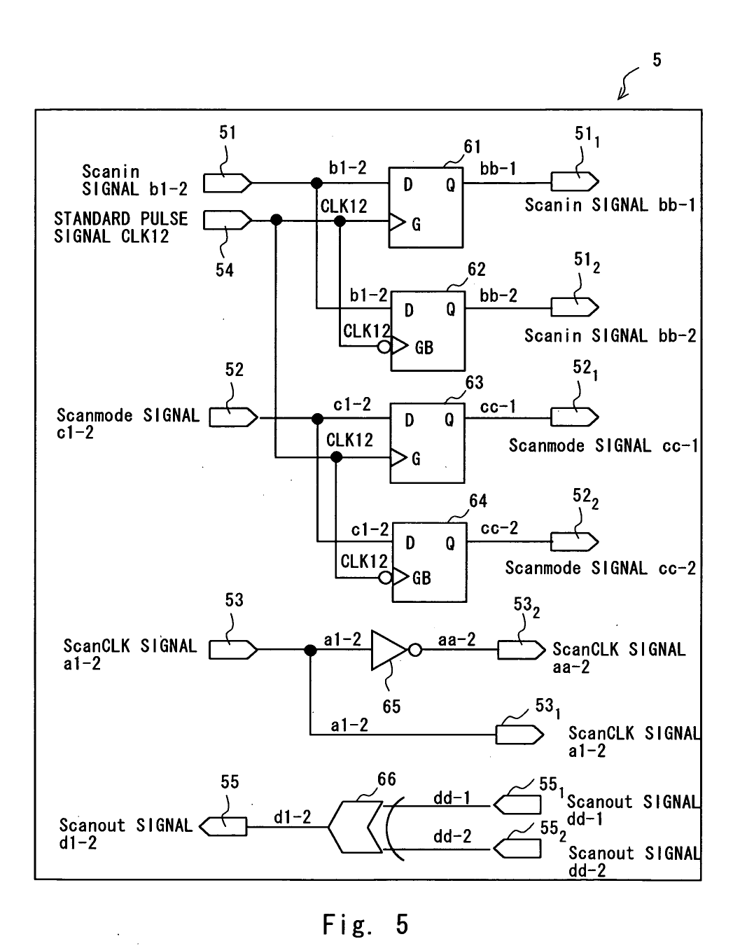

The division multiplexing circuit 5 will be described below in greater detail. FIG. 4 illustrates the signals inputted into the division multiplexing circuit 5 and outputted therefrom. FIG. 5 is a circuit diagram illustrating the division multiplexing circuit 5.

As shown in FIG. 4, the division multiplexing circuit 5 exchanges signals S₀ with an external testing device (tester), which is not shown in the figure, via the external terminals 8A for testing, exchanges signals S₁ with the scan control circuit 3 of the integrated circuit IC1, and exchanges signals S₂ with the scan control circuit 13 via the internal terminals 7B, 7C for testing which are connected to the integrated circuit IC2.

The signals S₀ are a Scanmode signal c1-2 obtained by multiplexing the Scanmode signals, a ScanCLK signal a1-2 obtained by multiplexing the ScanCLK signals and a Scanin signal b1-2 obtained by multiplexing the Scanin signals, among the scan path test signals of the internal cell 2 and internal cell 12, those signals being inputted from the outside, and a Scanout signal d1-2 which is the output signal obtained by multiplexing the Scanout signal dd-1 and Scanout signal dd-2 from the integrated circuit IC1 and integrated circuit IC1.

Further, the signals S₁ are a Scanmode signal cc-1, a ScanCLK signal a1-2 and Scanin signal bb-1 for inputting into the scan control circuit 3 of the integrated circuit IC1 and Scanout signal dd-1 which is inputted from the scan control circuit 3. Further, the signals S₂ are a Scanmode signal cc-2, a ScanCLK signal aa-2, a Scanin signal bb-2, for inputting into the scan control circuit 13 of the integrated circuit IC2, and a Scanout signal dd-2, which is inputted from the scan control circuit 3.

The division multiplexing circuit 5, as shown in FIG. 5, has input terminals 51 to 54 for inputting the Scanin signal b1-2, Scanmode signal c1-2, ScanCLK signal a1-2, and a standard pulse signal CLK12 from pulse generation circuit 6.

Further, there are provided output terminal 51₁, 51₂ for outputting the Scanin signals bb-1, bb-2, output terminal 52₁, 52₂ for outputting the Scanmode signals cc-1, cc-2, and output terminals 53₁, 53₂ for outputting the ScanCLK signals a1-2, aa-2 so that those Scanin signal b1-2, Scanmode signal c1-2, and ScanCLK signal a1-2 be divided in this division multiplexing circuit 5 and inputted in parallel into the scan control circuits 3, 13 of the integrated circuit IC1, IC2.

The division multiplexing circuit 5 further comprises a high-level latch 61 for latching the Scanin signal b1-2 within the H interval of the standard pulse signal CLK12 and outputting it as the Scanin signal bb-1, a low-level latch 62 for latching the Scanin signal b1-2 within the L interval of the standard pulse signal CLK12 and outputting it as the Scanin signal bb-2, a high-level latch 63 for latching the Scanmode signal c1-2 within the H interval of the standard pulse signal CLK12 and outputting it as the Scanmode signal cc-1, and a low-level latch 64 for latching the Scanmode signal c1-2 within the L interval of the standard pulse signal CLK12 and outputting it as the Scanmode signal cc-2. It also comprises an inverter 65 for inverting the Scanclock signal a1-2 into a ScanCLK signal aa-2. Further, the Scanclock signal a1-2 inputted from the input terminal 53 is outputted from the output terminal 53, as the ScanCLK signal a1-2 of the integrated circuit IC1.

Furthermore, it also has an input terminal 55₁ for inputting a Scanout signal dd-1 from the scan control circuit 3, an input terminal 55₂ for inputting the Scanout signal dd-2 from the scan control circuit 13, an Ex-OR circuit 66 for finding the exclusive disjunction thereof, and an output terminal 55 for outputting the Scanout signal d1-2 which is the output of the Ex-OR circuit 66.

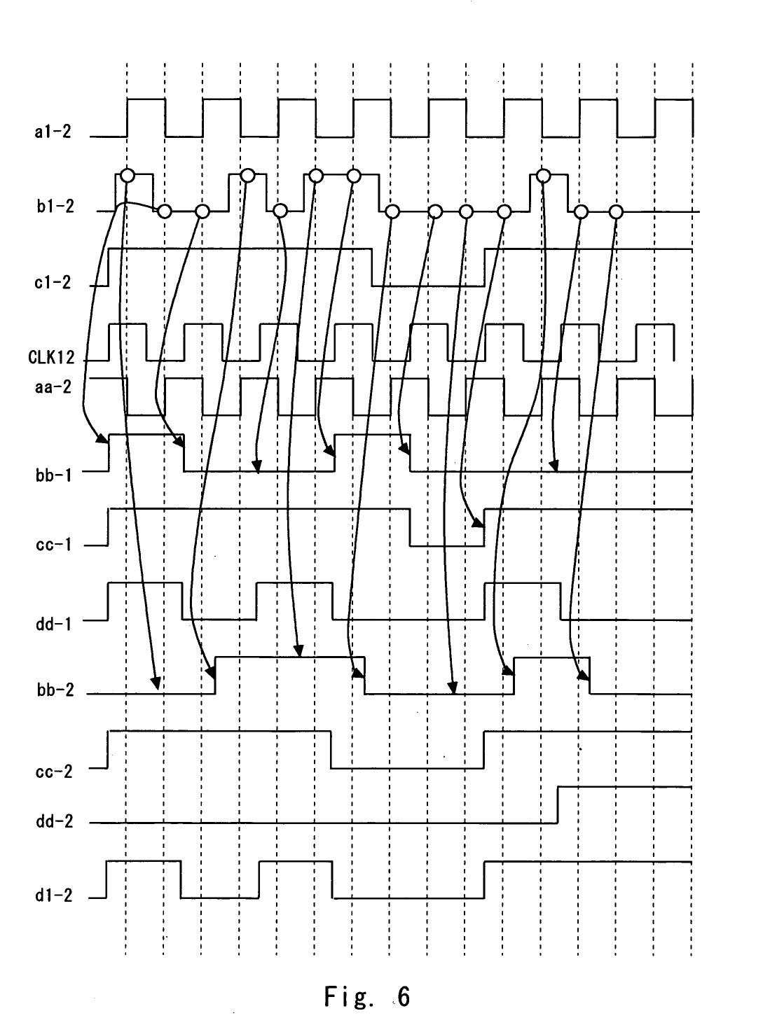

FIG. 6 is a timing chart of the signals inputted into the division multiplexing circuit shown in FIG. 5 and signals outputted upon conversion with the division multiplexing circuit. The ScanCLK signal a1-2 is inverted with the inverter 65 and becomes the ScanCLK signal aa-2. Further, the Scanin signal b1-2 is inputted together with the CLK12 into the high-level latch 61 and converted into the Scanin signal bb-1. Further, the Scanin signal b1-2 is inputted together with the CLK12 into the low-level latch 62 and converted into the Scanin signal bb-2.

Further, the Scanmode signal c1-2 is inputted together with the CLK12 into the high-level latch 63 and low-level latch 64 and converted into the Scanmode signal cc-1 and Scanmode signal cc-2, respectively. Further, the Scanmode signal dd-1 and Scanmode signal dd-2 are inputted into the Ex-OR circuit 66 and converted into the Scanmode signal d1-2.

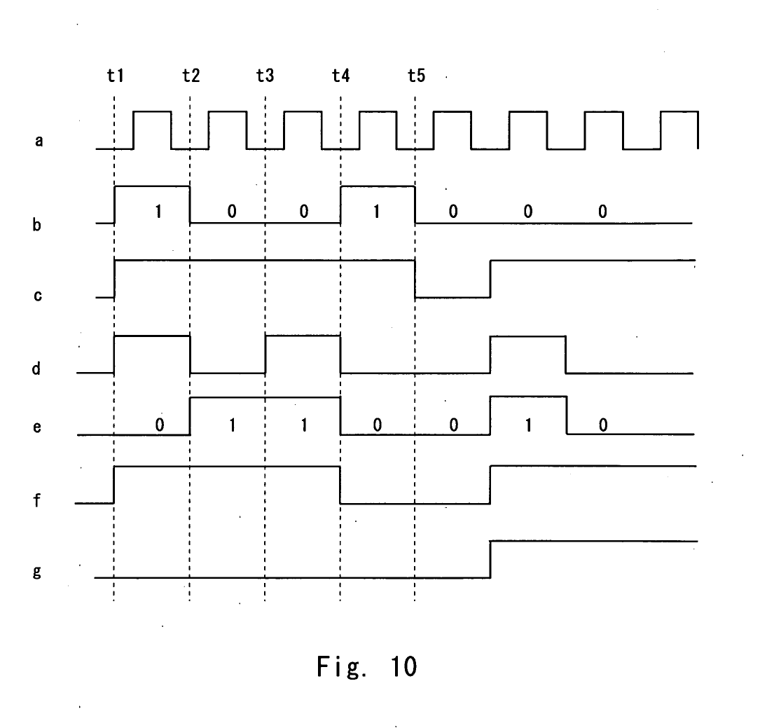

Here, in the above-described Conventional Example 1 shown in FIG. 9 and FIG. 10, when a scan path test of the two integrated circuits, the integrated circuit IC11 and integrated circuit IC12, is conducted, “10010001” is inputted as a Scanin signal into the scan control circuit of one integrated circuit, and a “0110010” pulse waveform is inputted as a Scanin signal into the scan control circuit of the other integrated circuit.

In the present embodiment, when a test is conducted similarly to Conventional Example 1 shown in FIG. 10, the clock period of scanin signal is set to be identical to the clock period of the scanin signal shown in FIG. 10, and the pulse waveform obtained by multiplexing the front half portion of this one period on the value of the Scanin signal b shown in FIG. 10 and the rear half portion of this one period on the value of the Scanin signal e shown in FIG. 10 is used as a scanin signal b1-2 which is the external input signal.

The high-level latch 61 takes in the scanin signal b1-2 connected to the high-level latch data input D within the H (high) period of the standard pulse CLK12, and the CLK12 holds the data of the L (low) period. As a result, the Q output of the high-level latch 62 becomes the Scanin signal bb-1.

The Scanin signal bb-1 shown in FIG. 6 is a pulse identical to the scanin signal b (FIG. 10) of the above-described Conventional Example 1 shown in FIG. 10. Furthermore, at the same time, the scanin signal b1-2 is taken in from the input D in the L period of the standard pulse CLK12 from the low-level latch 62, and in the low-level latch 62, the CLK12 holds the data of the H period. As a result, the output of the low-level latch 62 becomes the Scanin signal bb-2. This signal is a pulse delayed by half a period with respect to the scanin signal b (FIG. 10) of Conventional Example 1 shown in FIG. 10.

Further, if a pulse identical to the ScanCLK signal a (FIG. 10) of FIG. 10 is inputted as the ScanCLK signal a1-2, then the ScanCLK signal aa-2 that passed through the inverter 65 becomes an inverted signal of the ScanCLK signal a1-2, but this signal is delayed by half a period with respect to the ScanCLK signal a1-2. Thus, the relationship between the ScanCLK signal aa-2 and Scanin signal bb-2 is identical to that of the ScanCLK signal a and the scanin terminal signal e shown in FIG. 10. Further, the Scanmode signal cc-1 and Scanmode cc-2 are converted similarly to the Scanin signal b1-2 and so as to obtain the same relationship.

The exclusive OR of the scan path output scanout signals dd-1, dd-2 from the integrated circuit IC1 and integrated circuit IC2 is outputted by the Ex-OR circuit 66. Thus, when the scanout signals dd-1, dd-2 are of the same level, a L (low) signal is obtained, and when they are of different levels, a H (high) signal is obtained, and those signals are outputted from the package external terminal 8a as the signal (Scanout signal d1-2) obtained by multiplexing the scanout signals dd-1, dd-2.

As described hereinabove, the external input signals inputted as the serial signals are dived by the division multiplexing circuit 5 into scan path test signals as the parallel signals corresponding to two internal cells. The scanout signals from the two internal cells are multiplexed by the same circuit and outputted as one scanout signal d1-2. As a result, only the division multiplexing circuit 5 may be connected to the package external terminal for the test and, therefore, the number of external terminals for the test can be minimized. Furthermore, conversion to two scan path test signals and parallel output to the scan control circuits 3, 13 by the division multiplexing circuit 5 makes it possible to execute the scan path test almost simultaneously.

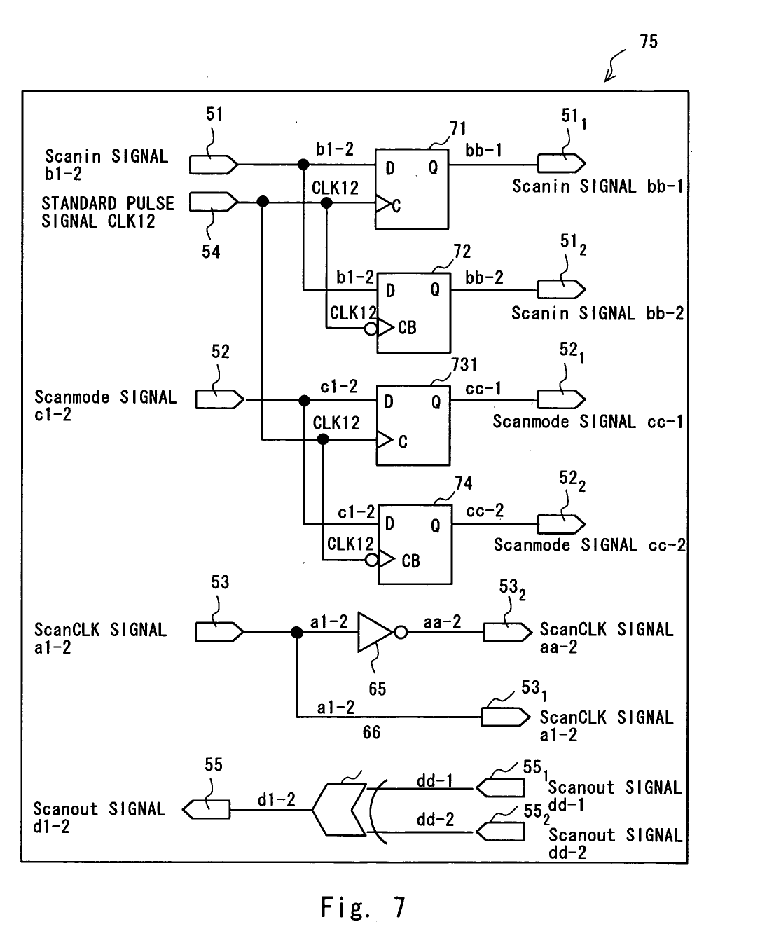

The modification example of the present embodiment will be described below. This modification example is a multichip module comprising a division multiplexing circuit 75 with a configuration different from that of the division multiplexing circuit 5 shown in FIG. 5. The configuration of the multichip module is identical to that shown in FIG. 1, except the configuration of the division multiplexing circuit, and here only the division multiplexing circuit 75 will be explained. FIG. 7 is a circuit diagram illustrating the division multiplexing circuit 75 of the present modification example. In the modification example shown in FIG. 7, the constituent elements identical to those of the division multiplexing circuit 5 shown in FIG. 5 are assigned with the same reference symbols and the detailed explanation thereof is omitted.

As shown in FIG. 7, in the division multiplexing circuit 75 of the present modification example, the high-level latches 61, 63 in the division multiplexing circuit 5 shown in FIG. 5 are replaced with high-edge flip-flops 71, 73, and the low-level latches 62, 63 are replaced with low-edge flip-flops 72, 73. In other aspects, the configuration is identical to that of the division multiplexing circuit 5 shown in FIG. 5.

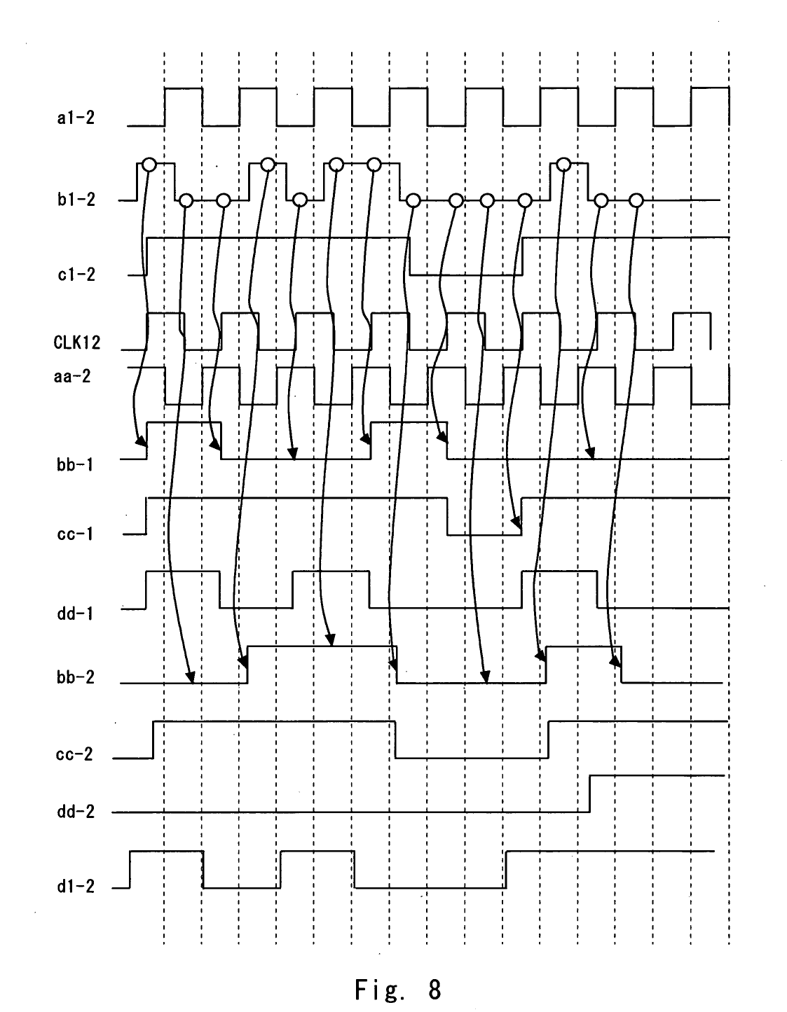

As described hereinabove, when a test similar to the conventional circuit shown in FIG. 10 is conducted, the timing chart of the signals inputted into the division multiplexing circuit 75 and signals outputted therefrom becomes a chart shown in FIG. 8. Thus, in the present modification example, too, similarly to the case illustrated by FIG. 5, the ScanCLK signal a1-2 is used as the ScanCLK signal of the integrated circuit IC1, and the signal obtained by inverting it with the inverter 65, that is, the signal obtained by delaying the ScanCLK signal a1-2 by half a period is used as the ScanCLK signal aa-2 of the integrated circuit IC2.

Further, with the timing shown in FIG. 8, the pulse waveforms of the Scanin signal b1-2 and Scanmode signal c1-2 are provided. As a result, the high-edge flip-flop 71 takes in the scanin signal b1-2 inputted into the data input D at the rising edge of the standard pulse CLK12 and holds the data till the next rising interval of the CLK12. As a result, the Q output of the high-edge flip-flop 71 becomes the Scanin signal bb-1. As for the scanin signal b1-2, the low-edge flip-flop 72 takes in the D input scanin signal b1-2 at the falling edge of the standard pulse CLK12 and holds the data till the next fall of the CLK12. As a result, the output of the low-edge flip-flop 72 becomes the Scanin signal bb-2.

Similarly, the Scanmode signal c1-2 becomes the Scanmode signal cc-1 and Scanmode signal cc-2 via the high-edge flip-flop 73 and low-edge flip-flop 74, respectively, and both input signals are divided into an input signal inputted into the integral circuit IC1 and an input signal inputted into the integrated circuit IC2.

In the present embodiment of the above-described configuration, only one integrated circuit IC1 of the integrated circuits carried in the multichip package is connected to the external terminal 8A for testing of the package 1, and the test signal for conducting the scan path test of the integrated circuit IC1 and the test signal for conducting the scan path test of the other integrated circuit IC2 are multiplexed and inputted via the external terminals 8A for testing into the integrated circuit IC1. Further, in the division multiplexing circuit 5 or division multiplexing circuit 75, those signals are converted into the test signals of integrated circuit IC1 and integrated circuit IC2 and the converted test signals are outputted in parallel into the scan control circuits 3, 13. The test signals for the integrated circuit IC2 are sent via the internal terminal connecting the integrated circuit IC1 and integrated circuit IC2. Therefore, only the integrated circuit IC1 is required to be connected to the external terminal of the package in order to input the test signals. For example, comparison with the above-described package shown in FIG. 9 demonstrates that the external terminal for testing, which is designed for inputting the test signals into the integrated circuit IC2, is not necessary.

Thus, in the present embodiment, only one external terminal for testing can be provided, the number of package external terminals used as the test terminals can be minimized and the number of package external terminals for testing is minimal. Therefore, the scan path test after mounting is also facilitated.

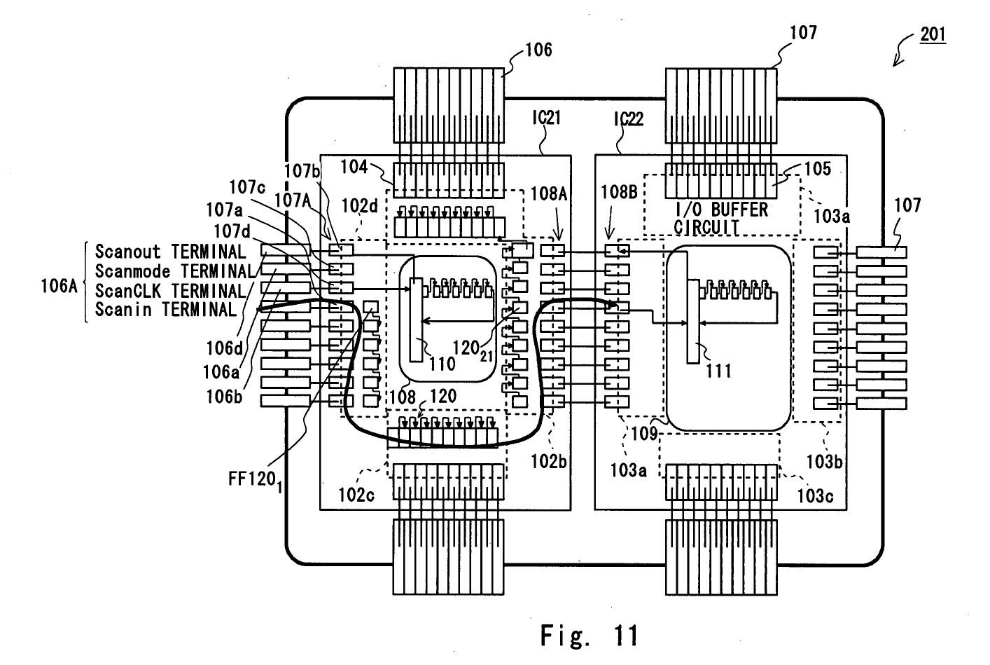

Further, for example, in comparison with the conventional circuit shown in FIG. 11, in the integrated circuit IC2, the overhead of the scan path test is increased, but in the multichip module of the present embodiment, dividing the multiplexed test signals and inputting them in parallel into the test control circuits makes it possible to reduce the overhead interval and to conduct individual scan path tests of each chip of the multichip and module almost simultaneously.

It is apparent that the present invention is not limited to the above embodiment, that may be modified and changed without departing from the scope and spirit of the invention. For example, the above-described division multiplexing circuit was explained as converting one external input signal into two scan path test signals, but it may be also used for converting into three or more scan path test signals. Furthermore, the division multiplexing circuit was explained as one circuit, but a division circuit for dividing the multiplexed signals and a multiplexing circuit for multiplexing the Scanout signals from each integrated circuit may be provided separately. Further, in the case of multichip packages carrying multiple integrated circuits, the integrated circuits carried in the package may be divided into blocks, a division multiplexing circuit may be provided for each block and conversion may be conducted to test signals for each integrated circuit.

1. A semiconductor device carrying a plurality of integrated circuits, comprising:
a plurality of external terminals;
two or more integrated circuits as test objects; and
a signal conversion circuit for receiving external input signals from the external terminals, converting the external input signals into test signals for each integrated circuit with respect to the two or more integrated circuits, and outputting the converted test signals to each of the two or more integrated circuits.

2. The semiconductor device according to claim 1, wherein
the signal conversion circuit receives signals indicating the test results from the respective integrated circuits, converts the signals into one signal, and outputs the same.

3. The semiconductor device according to claim 1, comprising first and second test signal control circuits for controlling respectively first and second test signals for testing first and second integrated circuits, respectively, wherein
the signal conversion circuit converts the external input signals into the first and second test signals and outputs the signals to the first and second test signal control circuits, respectively.

4. The semiconductor device according to claim 2, wherein
the external input signals are obtained by multiplexing the first and second test signals for testing the first integrated circuit and second integrated circuit, respectively, and
the signal conversion circuit comprises division circuit for dividing the external input signals into the first and second test signals and multiplexing circuit for multiplexing the signals indicating the test results from the respective integrated circuits.

5. A test method for a semiconductor device carrying a plurality of integrated circuits, comprising:
receiving external input signals via external terminals;
converting the external input signals into test signals for each integrated circuit with respect to two or more integrated circuits serving as test objects;
outputting the converted test signals to the two or more integrated circuits; and
receiving signals indicating the test results from the respective integrated circuits and, converting the received signals into one signal and outputting the same.

6. The test method for a semiconductor device according to claim 5, wherein
the external input signals are obtained by multiplexing first and second test signals for testing a first integrated circuit and a second integrated circuit, respectively,
the converting step of converting the external input signal comprises dividing the external input signals into the first and second test signals, and
the converting step of the converting the received signal comprises multiplexing the received signals indicating the test results from the respective integrated circuits.
